(19) United States
(12) Patent Application Publication
(10) Pub. No.: US 2006/0017153 A1
(43) Pub. Date: Jan. 26, 2006

(54) Interconnections of semiconductor device and method of forming the same

(75) Inventor: Ja-Young Choi, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/186,978

(22) Filed: Jul. 21, 2005

(30) Foreign Application Priority Data
Jul. 22, 2004 (KR) 10-2004-0057333

(51) Int. Cl. H01L 23/12; H01L 21/4763

(52) U.S. Cl. 257/700; 257/758; 438/622

(57) ABSTRACT

An interconnection structure includes a substrate containing a first lower interconnection and a pair of second interconnections separated from each other by a predetermined distance, and a metallic compound fuse pattern connecting the second lower interconnections, being positioned over the second lower interconnections. The fuse pattern is formed by using an upper electrode layer of a capacitor which is relatively thinner, without other interconnections involved in signal propagation speed, having reduced thickness regardless of increasing thickness of interconnections.

### CROSS-REFERENCE TO RELATED APPLICATIONS

This U.S. non-provisional patent application claims priority under 35 U.S.C. § 119 of Korean Patent Application 2004-57333 filed on Jul. 22, 2004, the entire contents of which are hereby incorporated by reference.

### BACKGROUND

The present invention is directed to interconnections of semiconductor devices, which in particular relates to a structure of interconnection for a semiconductor device, including pads for inputting and outputting external signals and fuses for selectively connecting and changing circuits to redundant circuits, and the method of forming the same.

Semiconductor devices generally contain unit elements formed in a substrate and interconnections electrically connecting the unit elements in accordance with designed layout patterns. Also included in the semiconductor devices are pads for inputting and outputting power source voltages and electric signals to conduct their own operations, and fuses for turning modules or unit elements to redundant circuits when they are determined as having failed.

Recently, it has become common to employ a dual damascene process with copper in manufacturing a semiconductor device for the sake of accomplishing high frequency operation, high quality signal output, and low product cost. As an example, U.S. Pat. No. 6,440,833, entitled “METHOD OF PROTECTING A COPPER PAD STRUCTURE DURING A FUSE OPENING PROCEDURE”, discloses a fuse structure of a semiconductor device and a method of forming the fuse structure.

FIG. 1 of the present application contains a schematic sectional diagram of a conventional semiconductor device.

As shown in FIG. 1, metal plug layers 2 and 3 are formed in a substrate 1. An interlevel insulation film 4 is deposited on the surface of the substrate 1, exposing the tops of the metal plug layers 2 and 3. Within regions confined by the interlevel insulation film 4, a metal interconnection layer 6a and a fuse layer 6b are formed by means of a copper damascene process.

On the resultant structure, interlevel insulation films 7, 8, 9, and 10 are deposited in sequence and patterned to form an opening. Then, a copper layer 16b and a barrier metal layer 17 are formed to fill the opening. After depositing passivation layers 18 and 19 over the structure, a bonding pad 30 is formed to be electrically connected to the copper layer 16b and a fuse opening 22 is formed over the fuse layer 6b.

As shown, the conventional structure uses some metal interconnections as fuse layers. Also, interconnections for transferring power or signals in a semiconductor device are preferred to be constructed with copper that has low resistivity because they are required to have low electrical resistance. The sheet resistance of the interconnection may be increased by extending the width thereof or by raising the thickness thereof.

It would be more advantageous to increase the thickness of the interconnection, rather than to extend the width of the interconnection, under consideration of integration efficiency. However, in case that the metal interconnections are partially used for the fuse layers, the increasing of the thickness may cause difficulty in opening the fuse interconnection. That is, in conducting a fuse opening process by a laser cutting technique to set a redundancy system for repairing defective circuits, an excessively thick fuse may be incompletely opened, and portions required to be completely cut may remain partially linked. Such a device may require, at least, a laser beam that is highly energized.

### SUMMARY OF THE INVENTION

The present invention is directed to an interconnection structure of a semiconductor memory and method of forming the same, which is not affected by an increase of the thickness.

According to one aspect, the invention provides an interconnection structure of a semiconductor device, having a metallic compound fuse formed of an upper capacitor electrode layer. The interconnection structure comprises: a substrate including a first lower interconnection and a pair of second lower interconnections formed in the substrate apart from each other. A metallic compound fuse pattern is formed over the second lower interconnections connecting the second lower interconnections with each other. First and second interlevel insulation films cover the substrate having the first and second lower interconnections and the fuse pattern. A fuse opening is formed in the first and second interlevel insulation films. A pad electrode is connected to the first lower interconnection in the first interlevel insulation film. A bonding pad is connected to the pad electrode through the second interlevel insulation film on the second interlevel insulation film. The metallic compound fuse pattern is the same material as the upper capacitor electrode layer.

In one embodiment, the structure further comprises a capacitor including: a lower capacitor electrode formed on the same level as the first and second lower interconnections; a capacitor dielectric film formed on the lower electrode; and an upper capacitor electrode formed on the capacitor dielectric film. The upper capacitor electrode is formed of the same material as the metal fuse pattern.

In one embodiment, the structure further comprises a capacitor interconnection linked to the upper capacitor electrode on the same level as the pad electrode.

In one embodiment, the structure further comprises a capping film covering the fuse pattern under the first interlevel insulation film, the capping film forming a bottom of the fuse opening.

In one embodiment, the metal is one of titanium nitride (TiN), tantalum nitride (TaN), and titanium tungsten (TiW).

In on embodiment, the structure further comprises the pad electrode is directly connected to the first lower interconnection.

According to another aspect, the invention is directed to an interconnection structure of a semiconductor device. The device includes a substrate and a first lower interconnection, a lower electrode, and a pair of second lower interconnections formed on the substrate separated from each other. A capacitor dielectric film and a upper capacitor electrode are stacked on the lower electrode. A fuse pattern is formed over the second lower interconnections connecting the second lower interconnections with each other. First and second interlevel insulation films cover the substrate having the first and second lower interconnections and the fuse pattern, a fuse opening being formed in the first and second interlevel insulation films. A pad electrode is connected to the first lower interconnection in the first interlevel insulation film. A bonding pad is connected to the pad electrode through the second interlevel insulation film on the second interlevel insulation film.

In one embodiment, the upper capacitor electrode and the fuse pattern are formed of metallic compounds.

In one embodiment, the metallic compound is one of titanium nitride (TiN), tantalum nitride (TaN), and titanium tungsten (TiW).

In one embodiment, the pad electrode is directly connected to the first lower interconnection.

In one embodiment, the structure further comprises a capping film covering the first lower interconnection, the upper capacitor electrode, and the fuse pattern, under the first interlevel insulation film, the capping film forming a bottom of the fuse opening.

In one embodiment, the first lower insulation film includes lower and higher interlevel insulation films stacked in sequence; and the pad electrode is formed of a via pattern connected to the first lower interconnection through the lower interlevel insulation film, and an upper interconnection connected to the via pattern in the upper interlevel insulation film.

In one embodiment, the structure further comprises a via pattern connected to the upper capacitor electrode through the lower interlevel insulation film and a capacitor interconnection connected to the via pattern in the upper interlevel insulation film.

In one embodiment, the upper capacitor electrode and the fuse pattern are covered by the lower interlevel insulation film.

In one embodiment, the fuse pattern is formed of the same material as an upper electrode of an MIM (metal-insulator-metal) capacitor. The MIM capacitor is constructed of a lower capacitor electrode formed on the same level with the first and second lower interconnections, a capacitor dielectric film formed on the lower electrode, and an upper capacitor electrode formed on the capacitor dielectric film. The upper capacitor electrode is formed of the same material as the metal fuse pattern.

The fuse opening makes an insulation film over the fuse pattern in a predetermined thickness, and the insulation film may be a capping film covering the fuse pattern under the first interlevel insulation film.

Another aspect of the invention is directed to a method of forming interconnections in a semiconductor device including a metallic compound fuse to connect interconnection layers on the interconnection layers. The method comprises: forming a first lower interconnection and a pair of second lower interconnections apart from each other on a substrate, forming a metallic compound fuse pattern over the second lower interconnections to connect the second lower interconnections with each other, forming a first interlevel insulation film on the resultant structure having the fuse pattern, forming a pad electrode connected to the first lower interconnection through the first interlevel insulation film, forming a second interlevel insulation film on the resultant structure having the pad electrode, patterning the second interlevel insulation film to form a pad opening exposing the pad electrode, forming a bonding pad connected to the pad electrode in the pad opening, removing the first and second interlevel insulation films over the fuse pattern in a predetermined depth to form a fuse opening.

In one embodiment, a capping film is conformably formed on the structure having the fuse pattern. The pad electrode is connected to the first lower interconnection through the capping film and the fuse opening is formed to expose the capping layer.

In one embodiment, the metallic compound is one of titanium nitride (TiN), tantalum nitride (TaN), and titanium tungsten (TiW).

In one embodiment, forming the pad electrode comprises forming a capacitor interconnection connected to the upper capacitor electrode through the first interlevel insulation film.

According to another aspect, the invention is directed to a method of forming interconnections in a semiconductor device. The method includes: forming a first lower interconnection, a lower electrode, and a pair of second lower interconnections apart from each other on a substrate; forming a dielectric film on the resultant structure including the first lower interconnection, the lower electrode, and the second lower interconnections, the dielectric film being associated with a fuse region in which the second lower interconnections are exposed; forming a metallic compound layer on the resultant structure including the dielectric film; patterning the metallic compound layer and the dielectric film to form a capacitor film and an upper electrode, and forming a fuse pattern to connect the second lower interconnections with each other in the fuse region; forming a first interlevel insulation film on the resultant structure including the pad electrode; forming a pad electrode connected to the first lower interconnection through the first interlevel insulation film; forming a second interlevel insulation film having a pad opening to expose the pad electrode on the resultant structure including the pad electrode; forming a bonding pad connected to the pad electrode in the pad opening; and patterning the first and second interlevel insulation films to form a fuse opening over the fuse pattern.

In one embodiment, the metallic compound is one of titanium nitride (TiN), tantalum nitride (TaN), and titanium tungsten (TiW).

In one embodiment, the method further comprises, before forming the first interlevel insulation film, conformably forming a capping film on the entire surface of the substrate. The pad electrode is connected to the first lower interconnection through the capping film and the fuse opening is formed to expose the capping layer.

In one embodiment, forming the first interlevel insulation film and the pad electrode comprises: stacking lower and upper interlevel insulation films on the substrate in sequence to form a first interlevel insulation film; patterning the upper and lower interlevel insulation films in sequence to form a via hole exposing the first lower interconnection and an interconnection groove extending on the lower interlevel insulation film; and filling the via hole and interconnection groove with a conductive film to form a pad electrode that is composed of a via pattern connected to the first lower interconnection and an upper interconnection layer connected to the via pattern.

In one embodiment, forming the via hole and interconnection groove comprises further forming a via hole and an interconnection groove and forming a capacitor interconnection composed of a via pattern connected to the upper electrode and an upper interconnection connected to the via pattern.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity. FIG. 1 is a schematic sectional diagram of a conventional semiconductor device.

FIG. 2 is a schematic sectional diagram illustrating an interconnection structure of a semiconductor device in accordance with a preferred embodiment of the invention.

FIGS. 3 through 8 are schematic sectional diagrams illustrating a process of forming an interconnection structure in accordance with a preferred embodiment of the invention.

### DETAILED DESCRIPTION OF PREFERRED EMBODIMENTS

Preferred embodiments of the present invention will be described below in more detail with reference to the accompanying drawings. It will be understood that when a layer is referred to as being on another layer or substrate, it can be directly on the other layer or substrate, or intervening layers may also be present.

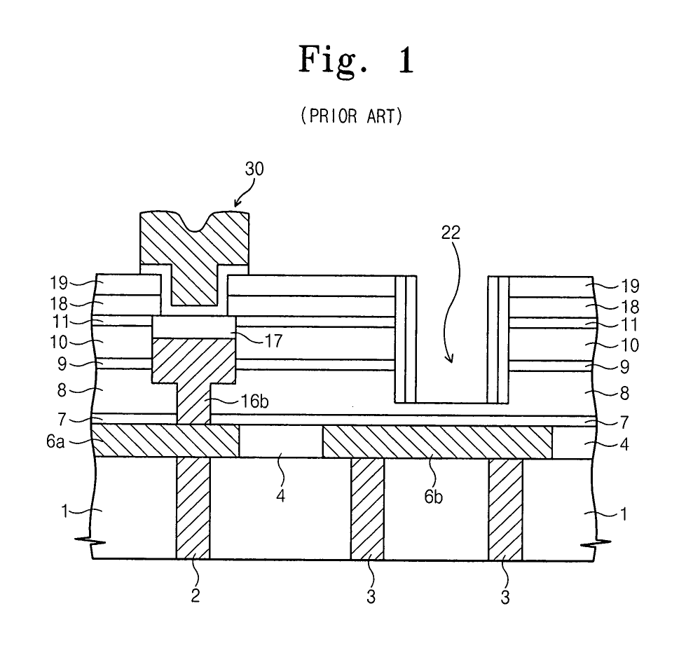

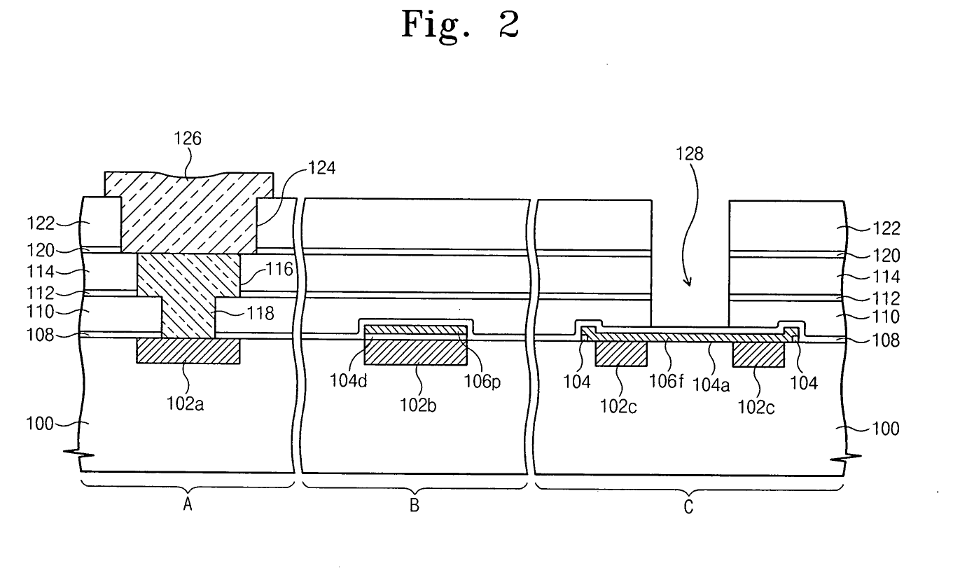

FIG. 2 is a sectional diagram illustrating an interconnection structure of a semiconductor device in accordance with a preferred embodiment of the invention.

Referring to FIG. 2, a lower interconnection layer is formed in a substrate 100 in which a pad region A, a capacitor region B, and a fuse region C are defined. The lower interconnection layer includes a first lower interconnection 102a formed in the pad region A, a lower capacitor electrode 102b formed in the capacitor region B, and a second lower interconnection 102c formed in the fuse region C. The first and second lower interconnections, 102a and 102c, and the lower capacitor electrode 102b may be designed to be interconnected with each other.

The lower interconnection layer may be made of copper (Cu) having excellent conductivity. On the lower capacitor electrode 102b, a capacitor dielectric film 104d and an upper capacitor electrode 106p are stacked in sequence. On the second lower interconnections 102c formed apart from each other in the fuse region C, a fuse pattern 106f is formed of the upper capacitor electrode layer.

The upper capacitor electrode 106p and the fuse pattern 106f may be formed of a metallic compound used as a barrier metal in constructing a metal interconnection of a semiconductor device, e.g., titanium nitride (TiN), tantalum nitride (TaN), or titanium tungsten (TiW). A material 104 forming the capacitor dielectric film 104d may partially remain at the edges of the fuse pattern 106f.

A conformal capping film 108 covers the overall structure of the substrate 100 in which the upper capacitor electrode 106p and the fuse pattern 106f are formed. On the capping film 108, interlevel insulation films 110, 114, and 122 are deposited. Etch stopping layers 112 and 120 may be interposed among the interlevel insulation films 110, 114, and 122. An upper interconnection layer is formed through the first interlevel insulation film composed of the lower and upper interlevel insulation films 110 and 114. The upper interconnection layer may be formed by means of a copper damascene process. Although not shown, the upper interconnection layer may be connected to the upper capacitor electrode 106p and electrically connected to the second lower interconnection 102c in a predetermined region. In the pad region A, a pad electrode 118 formed of the upper interconnection layer is connected to the first lower interconnection 102a through the first interlevel insulation film. A second interlevel insulation film 122 is formed on the first interlevel insulation film and a bonding pad 126 connected to the pad electrode 118 through the second interlevel insulation film 122 is formed in the pad region A. The bonding pad 126 may be made of aluminum. Over the fuse pattern 106f, a fuse opening 128 is formed by removing the interlevel insulation films thereon. The fuse opening 128 may be formed with an insulation film remaining in a predetermined thickness on the fuse pattern 106f. For instance, the capping film 108 on the fuse pattern 106f can be exposed by the fuse opening 128.

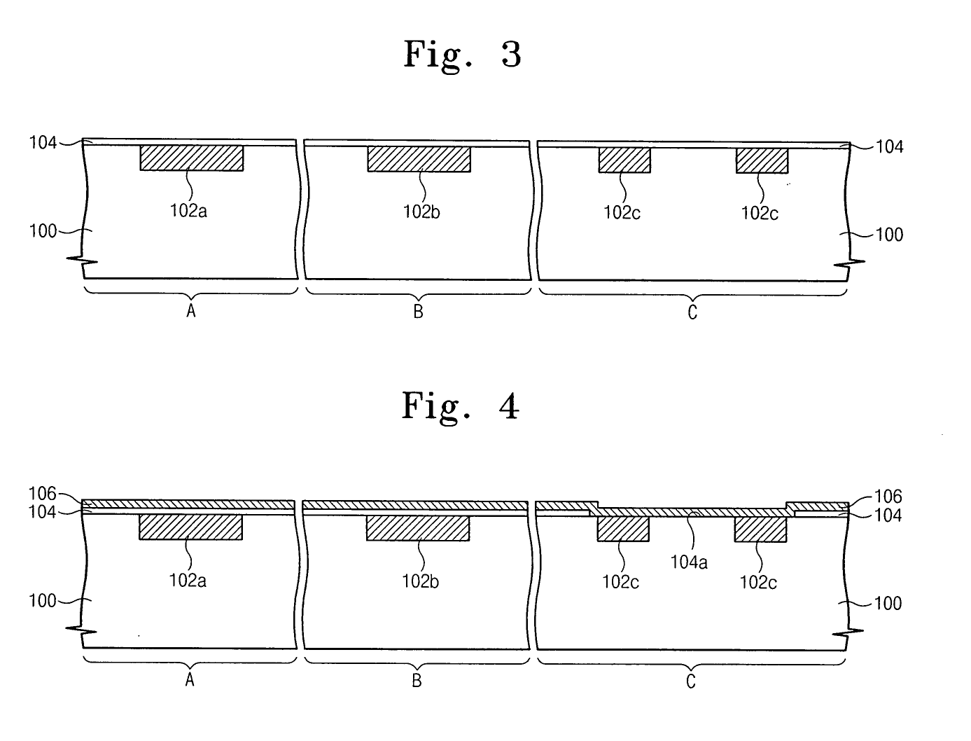

FIGS. 3 through 8 are sectional diagrams illustrating the process of forming an interconnection structure in accordance with a preferred embodiment of the invention.

First, referring to FIG. 3, the pad region A, the capacitor region B, and the fuse region C are defined in the substrate 100. The substrate 100 may be one in which passive and active components are formed and an insulation film is deposited on the components.

A lower interconnection layer is formed on the substrate 100. The lower interconnection layer may be formed by means of a copper damascene process. The first lower interconnection 102a is formed in the pad region A, the lower capacitor electrode 102b is formed in the capacitor region B, and the second lower interconnection 102c is formed in the fuse region C. The first and second lower interconnections, 102a and 102c, are designed to be electrically connectible with each other. Then, the dielectric film 104 is deposited on the overall structure of the substrate 100 having the lower interconnection layer that is composed of the first lower interconnection 102a, the lower capacitor electrode 102b, and the second lower electrode 102c.

Next, referring to FIG. 4, the dielectric film 104 is patterned to expose the second lower interconnections 102c in the fuse region C. Then, the upper capacitor electrode layer 106 is formed on the overall structure of the substrate 100 in which the fuse region C is completely formed. The upper capacitor electrode layer 106 may be formed of a metallic compound such as titanium nitride (TiN), tantalum nitride (TaN), or titanium tungsten (TiW).

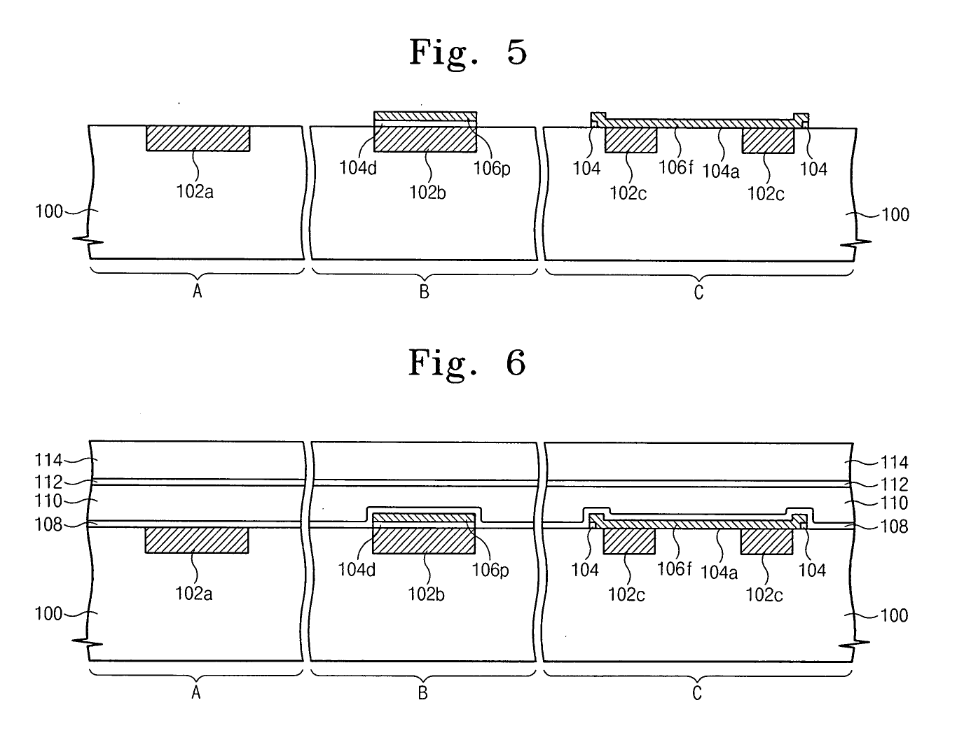

Next, referring to FIG. 5, the upper capacitor electrode layer 106 and the dielectric film 104 are patterned in sequence to form the capacitor dielectric film 104d and the upper capacitor electrode 106p which are stacked on the lower capacitor electrode 102b in order. Simultaneously, the fuse pattern 106f is formed connecting the second lower interconnections 102c therein. According to the patterning position, portions of the dielectric film 104 may remain under the edges of the fuse pattern 106f.

Referring to FIG. 6, the capping film 108 is deposited on the overall structure of the substrate 100 having the upper capacitor electrode 106p and the fuse pattern 106f. The capping film 108 may be formed of silicon nitride, silicon oxynitride, or silicon carbide. The first interlevel insulation film, which is composed of the lower and upper interlevel insulation films 110 and 114, is formed on the overall structure of the substrate 100 having the capping film 108. The etch stopping layer 112 may be formed between the upper interlevel insulation film 114 and the lower interlevel insulation film 110.

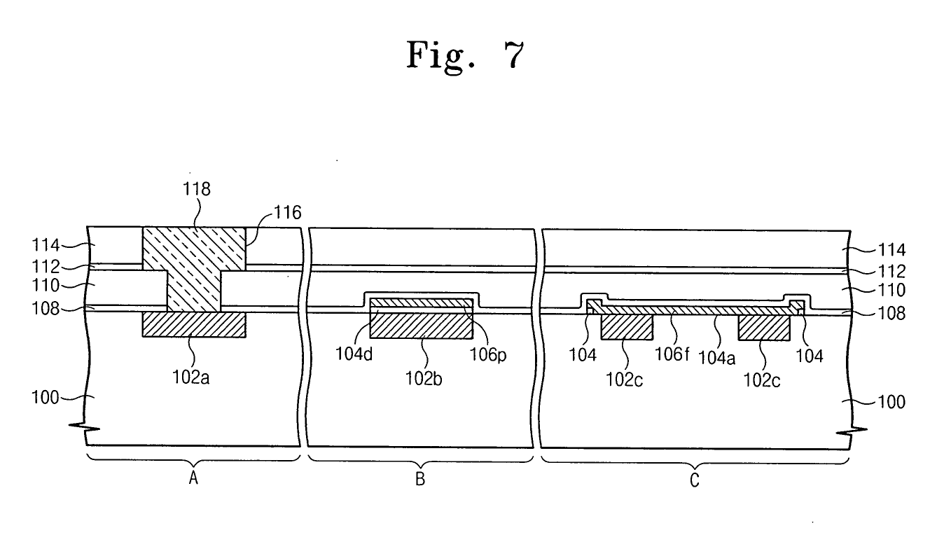

Next, referring to FIG. 7, employing the copper damascene processing technique, via holes and interconnection grooves 116 are formed partially exposing the first lower interconnection 102a, the upper capacitor electrode 106p, and the second lower interconnection 102c through the lower interlevel insulation film 110. The via holes and interconnection grooves 116 are patterned and formed in the upper interlevel insulation film 114. An upper electrode layer is formed of copper filling the via holes and the interconnection grooves 116. The upper electrode layer includes the pad electrode 118 connected to the first lower interconnection 102a, and an upper interconnection layer (not shown) positionally connected to the upper capacitor electrode 106p and the second lower interconnection 102c. The upper interconnection layer may be designed in a predetermined layout pattern.

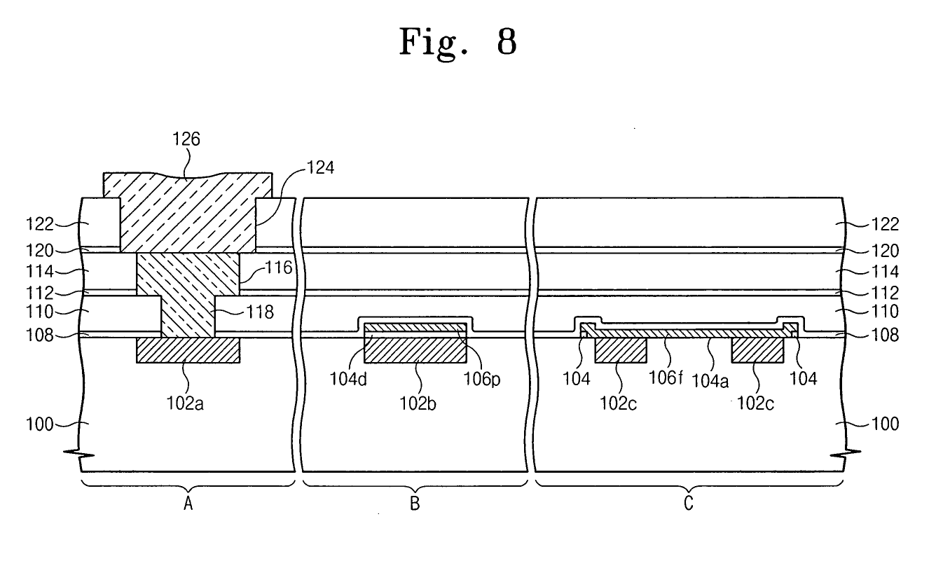

Finally, referring to FIG. 8, the etch stopping layer 120 is formed on the overall structure of the substrate 100 having the upper interconnection layer and the second interlevel insulation film 122 is formed on the etch stopping layer 120. The second interlevel insulation film 122 may be formed by stacking materials of series of silicon oxides and silicon nitrides in order to protect the device from the external environment.

Further in FIG. 8, the second interlevel insulation film 122 is patterned to form the pad opening 124 exposing the pad electrode 118. After an aluminum film is formed on the overall structure of the substrate 100 having the pad opening 124, the aluminum film is patterned to form the bonding pad that fills the pad opening 124 and is connected to the pad electrode 118.

The fuse opening 128 shown in FIG. 2 is formed by partially removing the first and second interlevel insulation films over the fuse region C. The fuse opening 128 may be formed leaving the first interlevel insulation film on the fuse pattern 106f by removing the second interlevel insulation film 122, or to expose the capping film on the fuse pattern 106f by entirely patterning the first and second interlevel insulation films.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

According to the invention, a thinner fuse pattern is formed while increasing thickness of interconnections, by patterning a fuse layer using the relatively thin upper capacitor electrode film, without using any relatively thicker interconnection layer involved in propagation speed of signals in the semiconductor device.

The invention provides a semiconductor device with improved operation characteristics increasing the thickness and sheet resistance of interconnections without defects in opening fuses.

What is claimed is:

1. An interconnection structure of a semiconductor device, comprising:
a substrate;
a first lower interconnection and a pair of second lower interconnections formed on the substrate separated from each other;
a metallic compound fuse pattern over the second lower interconnections connecting the second lower interconnections with each other;
first and second interlevel insulation films covering the substrate having the first and second lower interconnections and the fuse pattern, a fuse opening being formed in the first and second interlevel insulation films;
a pad electrode connected to the first lower interconnection in the first interlevel insulation film; and
a bonding pad connected to the pad electrode through the second interlevel insulation film on the second interlevel insulation film,
wherein the metallic compound fuse pattern is the same material as an upper capacitor electrode layer.

2. The interconnection structure as set forth in claim 1, further comprising a capacitor including:
a lower capacitor electrode formed on the same level as the first and second lower interconnections; a capacitor dielectric film formed on the lower electrode; and an upper capacitor electrode formed on the capacitor dielectric film,
wherein the upper capacitor electrode is formed of the same material as the metal fuse pattern.

3. The interconnection structure as set forth in claim 2, further comprising a capacitor interconnection linked to the upper capacitor electrode on the same level as the pad electrode.

4. The interconnection structure as set forth in claim 1, further comprising a capping film covering the fuse pattern under the first interlevel insulation film, the capping film forming a bottom of the fuse opening.

5. The interconnection structure as set forth in claim 1, wherein the metal is one of titanium nitride (TiN), tantalum nitride (TaN), and titanium tungsten (TiW).

6. The interconnection structure as set forth in claim 1, wherein the pad electrode is directly connected to the first lower interconnection.

7. An interconnection structure of a semiconductor device, comprising:
a substrate;
a first lower interconnection, a lower electrode, and a pair of second lower interconnections being formed on the substrate separated from each other;
a capacitor dielectric film and a upper capacitor electrode stacked on the lower electrode;
a fuse pattern over the second lower interconnections connecting the second lower interconnections with each other;
first and second interlevel insulation films covering the substrate having the first and second lower interconnections and the fuse pattern, a fuse opening being formed in the first and second interlevel insulation films;
a pad electrode connected to the first lower interconnection in the first interlevel insulation film; and
a bonding pad connected to the pad electrode through the second interlevel insulation film on the second interlevel insulation film.

8. The interconnection structure as set forth in claim 7, wherein the upper capacitor electrode and the fuse pattern are formed of metallic compounds.

9. The interconnection structure as set forth in claim 8, wherein the metallic compound is one of titanium nitride (TiN), tantalum nitride (TaN), and titanium tungsten (TiW).

10. The interconnection structure as set forth in claim 7, wherein the pad electrode is directly connected to the first lower interconnection.

11. The interconnection structure as set forth in claim 7, further comprising a capping film covering the first lower interconnection, the upper capacitor electrode, and the fuse pattern, under the first interlevel insulation film, the capping film forming a bottom of the fuse opening.

12. The interconnection structure as set forth in claim 7, wherein the first lower insulation film includes lower and higher interlevel insulation films stacked in sequence; and
wherein the pad electrode is formed of a via pattern connected to the first lower interconnection through the lower interlevel insulation film, and an upper interconnection connected to the via pattern in the upper interlevel insulation film.

13. The interconnection structure as set forth in claim 12, further comprising: a via pattern connected to the upper capacitor electrode through the lower interlevel insulation film; and a capacitor interconnection connected to the via pattern in the upper interlevel insulation film.

14. The interconnection structure as set forth in claim 12, wherein the upper capacitor electrode and the fuse pattern are covered by the lower interlevel insulation film.

15. A method of forming interconnections in a semiconductor device, the method comprising:
forming a first lower interconnection and a pair of second lower interconnections apart from each other on a substrate;
forming a metallic compound fuse pattern over the second lower interconnections to connect the second lower interconnections with each other;
forming a first interlevel insulation film on the resultant structure having the fuse pattern;
forming a pad electrode connected to the first lower interconnection through the first interlevel insulation film;
forming a second interlevel insulation film on the resultant structure having the pad electrode;
patterning the second interlevel insulation film to form a pad opening exposing the pad electrode;
forming a bonding pad connected to the pad electrode in the pad opening;
removing the first and second interlevel insulation films over the fuse pattern in a predetermined depth to form a fuse opening.

16. The method as set forth in claim 15, further comprising conformably forming a capping film on the resultant structure having the fuse pattern,
wherein the pad electrode is connected to the first lower interconnection through the capping film and the fuse opening is formed to expose the capping layer.

17. The method as set forth in claim 15, wherein the metallic compound is one of titanium nitride (TiN), tantalum nitride (TaN), and titanium tungsten (TiW).

18. The method as set forth in claim 15, wherein forming the pad electrode comprises forming a capacitor interconnection connected to the upper capacitor electrode through the first interlevel insulation film.

19. A method of forming interconnections in a semiconductor device, the method comprising:
forming a first lower interconnection, a lower electrode, and a pair of second lower interconnections apart from each other on a substrate;
forming a dielectric film on the resultant structure including the first lower interconnection, the lower electrode, and the second lower interconnections, the dielectric film being associated with a fuse region in which the second lower interconnections are exposed;
forming a metallic compound layer on the resultant structure including the dielectric film;
patterning the metallic compound layer and the dielectric film to form a capacitor film and an upper electrode, and forming a fuse pattern to connect the second lower interconnections with each other in the fuse region;
forming a first interlevel insulation film on the resultant structure including the pad electrode;
forming a pad electrode connected to the first lower interconnection through the first interlevel insulation film;
forming a second interlevel insulation film having a pad opening to expose the pad electrode on the resultant structure including the pad electrode;
forming a bonding pad connected to the pad electrode in the pad opening; and
patterning the first and second interlevel insulation films to form a fuse opening over the fuse pattern.

20. The method as set forth in claim 19, wherein the metallic compound is one of titanium nitride (TiN), tantalum nitride (TaN), and titanium tungsten (TiW).

21. The method as set forth in claim 19, further comprising, before forming the first interlevel insulation film, conformably forming a capping film on the entire surface of the substrate,
wherein the pad electrode is connected to the first lower interconnection through the capping film and the fuse opening is formed to expose the capping layer.

22. The method as set forth in claim 19, wherein forming the first interlevel insulation film and the pad electrode comprises:
stacking lower and upper interlevel insulation films on the substrate in sequence to form a first interlevel insulation film;
patterning the upper and lower interlevel insulation films in sequence to form a via hole exposing the first lower interconnection and an interconnection groove extending on the lower interlevel insulation film; and
filling the via hole and interconnection groove with a conductive film to form a pad electrode that is composed of a via pattern connected to the first lower interconnection and an upper interconnection layer connected to the via pattern.

23. The method as set forth in claim 22, wherein forming the via hole and interconnection groove comprises further forming a via hole and an interconnection groove and forming a capacitor interconnection composed of a via pattern connected to the upper electrode and an upper interconnection connected to the via pattern.
